(19) United States
(12) Patent Application Publication
(10) Pub. No.: US 2026/0040636 A1
(43) Pub. Date: Feb. 5, 2026

(54) BACKSIDE LOCAL WELL TAP

(71) Applicant: International Business Machines Corporation, Armonk, NY (US)

(72) Inventors: Reinaldo Vega, Mahopac, NY (US); Xiaoming Yang, Clifton Park, NY (US); HUIMEI ZHOU, Albany, NY (US); Ruilong Xie, Niskayuna, NY (US); Brent Alan Anderson, Jericho, VT (US); Lawrence Alfred Clevenger, Saratoga Springs, NY (US); Albert Manhee Chu, Nashua, NH (US); Nicholas Anthony Lanzillo, Wynantskill, NY (US); LEI ZHUANG, Ridgefield, CT (US); Ravikumar Ramachandran, Pleasantville, NY (US); Mahender Kumar, Clifton Park, NY (US)

(21) Appl. No.: 18/791,949

(22) Filed: Aug. 1, 2024

(51) Int. Cl. H01L 29/06; H01L 23/528

(52) U.S. Cl. CPC H10D 62/116; H01L 23/5286

(57) ABSTRACT

Semiconductor devices are provided that include a conductor structure located in a shallow trench isolation structure that is positioned between two field effect transistors of a same conductivity type. The conductor structure is electrically connected to a backside contact structure, and the backside contact structure is electrically connected to at least one well region that straddles a sidewall of the backside contact structure. The area of contact between the backside contact structure and the well region provides a local well tap to the semiconductor device.

### BACKGROUND

The present application relates to semiconductor technology, and more particularly to a semiconductor device including a backside local well tap.

Backside power delivery refers to a novel technique where power supply lines are routed on the backside of a semiconductor chip or integrated circuit (IC), rather than the traditional frontside. Backside power delivery offers several advantages, including increased logic density and improved power and performance (better signal integrity, reduced noise and improved overall chip performance).

### SUMMARY

Semiconductor devices are provided that include a conductor structure (including a conductor contact pillar) located in a shallow trench isolation structure that is positioned between two field effect transistors of a same conductivity type. The conductor structure is electrically connected to a backside contact structure, and the backside contact structure is electrically connected to at least one well region that straddles a sidewall of the backside contact structure. The area of contact between the backside contact structure and the at least one well region provides a local well tap to the semiconductor device.

In one embodiment of the present application, the semiconductor device includes two transistors of a first conductivity type located on a surface of a well region of a second conductivity type that differs (i.e., is opposite) from the first conductivity type, a shallow trench isolation structure located between the two transistors of the first conductivity type, a conductor structure located in the shallow trench isolation structure and including at least a conductor contact pillar, and a backside contact structure electrically connected to a bottom surface of the conductor contact pillar and in direct contact with a sidewall of the well region that is located beneath each of the transistors of the first conductivity type.

In another embodiment of the present application, the semiconductor device includes two transistors of a first conductivity type located on a surface of a well region of a second conductivity type that differs from the first conductivity type, a shallow trench isolation structure located between the two transistors of the first conductivity type, a conductor structure located in the shallow trench isolation structure and including at least a conductor contact pillar, and a backside contact structure electrically connected to both a sidewall and a bottom surface of the conductor contact pillar of the conductor structure and in direct contact with a sidewall of the well region that is located beneath each of the transistors of the first conductivity type.

In yet another embodiment of the present application, the semiconductor device includes two transistors of a first conductivity type located on a surface of a well region of a second conductivity type that differs from the first conductivity type, a shallow trench isolation structure located between the two transistors of the first conductivity type, a conductor structure located in the shallow trench isolation structure and including at least a conductor contact pillar, and a backside contact structure electrically connected to both a sidewall and a bottom surface of the conductor contact pillar of the conductor structure and in direct contact with both a sidewall and a bottom surface of the well region that is located beneath each of the transistors of the first conductivity type.

In a further embodiment of the present application, the semiconductor device includes a pFET device region including two p-type field effect transistors (pFETs) located on a surface of an n-well region, a first shallow trench isolation structure located between the two pFETs, a first conductor structure located in the first shallow trench isolation structure and including at least a first conductor contact pillar, and a first backside contact structure electrically connected to at least a bottom surface of the first conductor contact pillar of the first conductor structure and in direct contact with a sidewall of the n-well region. The semiconductor device of this further embodiment also includes an nFET device region located adjacent to the pFET device region and including two nFETs located on a surface of a p-well region, a second shallow trench isolation structure located between the nFETs, a second conductor structure located in the second shallow trench isolation structure and including at least a second conductor contact pillar, and a second backside contact structure electrically connected to at least a bottom surface of the second conductor contact pillar of the second conductor structure and in direct contact with a sidewall of the p-well region.

### BRIEF DESCRIPTION OF THE DRAWINGS

FIG. 1 is a cross sectional view of an exemplary semiconductor device in accordance with an embodiment of the present application.

FIG. 2 is a cross sectional view of another exemplary semiconductor device in accordance with another embodiment of the present application.

FIG. 3 is a cross sectional view of a yet another exemplary semiconductor device in accordance with yet another embodiment of the present application.

FIG. 4 is a cross sectional view of an exemplary semiconductor structure that can be employed in accordance with the present application, the exemplary structure includes a semiconductor base layer, an n-well region and a p-well region located laterally adjacent to each other and on the semiconductor base layer, p-type field effect transistors (pFETs) located on the n-well region, n-type field effect transistors (nFETs) located on the n-well region, and shallow trench isolation openings located in both the n-well region and the p-well region.

FIG. 5 is a cross sectional view of the exemplary semiconductor structure of FIG. 4 after forming a shallow trench isolation structure in each of the shallow trench isolation openings.

FIG. 6 is a cross sectional view of the exemplary semiconductor structure of FIG. 5 after forming a conductor structure in each of the pFET device region and the nFET device region.

FIG. 7 is a cross sectional view of the exemplary semiconductor structure of FIG. 6 after removing the semiconductor base layer.

FIG. 8 is a cross sectional view of the exemplary semiconductor structure of FIG. 7 after forming a backside interlayer dielectric (ILD) layer, and forming backside contact openings that reveal a conductor contact pillar of each conductor structure.

FIG. 9 is a cross sectional view of the exemplary semiconductor structure of FIG. 8 after forming a backside contact structure in each of the backside contact openings.

FIG. 10 is a cross sectional view of the exemplary semiconductor structure of FIG. 4 after forming a mask that reveals one of the shallow trench isolation openings.

FIG. 11 is a cross sectional view of the exemplary semiconductor structure of FIG. 10 after extending the depth of the revealed shallow trench isolation opening to provide an extended depth shallow trench isolation opening between the pFET device region and the nFET device region.

FIG. 12 is a cross sectional view of the exemplary semiconductor structure of FIG. 11 after removing the mask.

FIG. 13 is a cross sectional view of the exemplary semiconductor structure of FIG. 12 after forming a shallow trench isolation structure in each shallow trench isolation opening, and an extended depth shallow trench isolation structure in the extended depth shallow trench isolation opening.

FIG. 14 is a cross sectional view of the exemplary semiconductor structure of FIG. 13 after forming a conductor structure in each of the pFET device region and nFET device region.

FIG. 15 is a cross sectional view of the exemplary semiconductor structure of FIG. 14 after removing the semiconductor base layer.

FIG. 16 is a cross sectional view of the exemplary semiconductor structure of FIG. 15 after forming a backside ILD layer, and forming backside contact openings that reveal a conductor contact pillar of each conductor structure.

FIG. 17 is a cross sectional view of the exemplary semiconductor structure of FIG. 16 after forming a backside contact structure in each of the backside contact openings.

FIG. 18 is a cross sectional view of the exemplary semiconductor structure of FIG. 7 after forming a backside ILD layer.

FIG. 19 is a cross sectional view of the exemplary semiconductor structure of FIG. 18 after forming a backside opening that reveals one of the shallow trench isolation structures.

FIG. 20 is a cross sectional view of the exemplary semiconductor structure of FIG. 19 after forming additional backside ILD material in the backside opening.

FIG. 21 is a cross sectional view of the exemplary semiconductor structure of FIG. 20 after forming backside contact structures.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. The transistors that can be employed in the present application are not limited to any specific type of transistor. Instead, the transistors that can be employed in the present application include, for example, planar transistors, finFETs, nanowire transistors, nanosheet transistors, or stacked transistors.

The semiconductor channel region is composed of a semiconductor material and can be in the form of a planar semiconductor layer, a semiconductor fin, a semiconductor nanowire or a vertical stack of semiconductor nanowires, a semiconductor nanosheet or a vertical stack of semiconductor nanowires. As used throughout the present application, the term “semiconductor material” denotes a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. The semiconductor channel region can be composed of a semiconductor material that provides high channel mobility for nFET devices or provides high channel mobility for pFET devices.

Each source/drain regions is composed of a semiconductor material and a dopant. As used herein, a “source/drain” region can be a source region or a drain region depending on subsequent wiring and application of voltages during operation of the transistor. The dopant that is present in the source/drain regions can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each source/drain region can have a dopant concentration of from 4×10²⁰ atoms/cm³ to 3×10²¹ atoms/cm³.

The gate structure includes a gate dielectric material and a gate electrode. As is known to those skilled in the art, a gate dielectric material directly contacts a physically exposed surface(s) of the semiconductor channel region, and a gate electrode is formed on the gate dielectric material. The gate dielectric material has a dielectric constant of 4.0 or greater. All dielectric constants mentioned herein are measured in a vacuum, unless stated to the contrary. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg). The gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof.

In the present application, the semiconductor device includes a frontside and a backside. The frontside includes a side of the device that includes at least one transistor. The backside of the semiconductor device is the side of the device that is opposite the frontside. The backside includes backside contact structures and can be designed for backside power delivery. In backside power delivery, a backside power distribution network structure is located beneath a backside ILD layer and it is typically connected to a source/drain region of a transistor by a combination of a backside contact structure and a conductor structure. The formation of a backside power distribution network structure requires backside substrate thinning which can pose a challenge for well tap placement, especially if the substrate is thinned past the bottom of a shallow trench isolation structure. Existing approaches to backside power distribution network structure formation either have thinned substrates (in which the thickness of the substrate is less than the thickness (i.e., depth) of the shallow trench isolation structure) with floating wells or thick substrates (in which the thickness of the substrate is greater than the thickness (i.e., depth) of the shallow trench isolation structure) with conventional well taps.

Well taps are used to drain away charge that can build up within a well region during operation of the device. If not removed, the built up charges can affect the operational behavior and performance of the device. Conventional well taps are located at the end of a cell and they consist of p-conductivity type structure in contact with an n-well region, or an n-conductivity type structure in contact with a p-well. In devices including conventional well taps, a resistive path from the well tap to most nested devices occurs in the middle of a circuit row. This limits/restricts the efficiency of the well tap. A more resistive path toward a well region in a given distance will affect the well potential. For example, in an nFET, the underlying p-well is typically biased to ground, while for a pFET, the underlying n-well is typically biased to the power supply voltage (VDD). If the access resistance to the well region is high, then the p-well voltage will be higher than ground while the n-well voltage will be lower than VDD. This will increase subthreshold leakage in the bulk portion of the device. A need exists for providing more efficient well taps in semiconductor devices that include a backside power distribution network structure. With backside power delivery, the substrate region is thinner, which means a thinner well region. A thinner well region will have higher resistance and so this possess a risk to well tap integrity for devices far away from a conventional well tap.

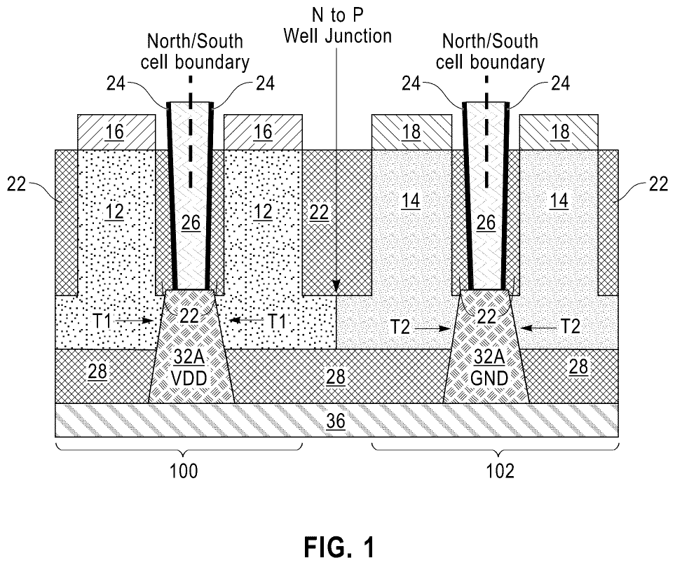

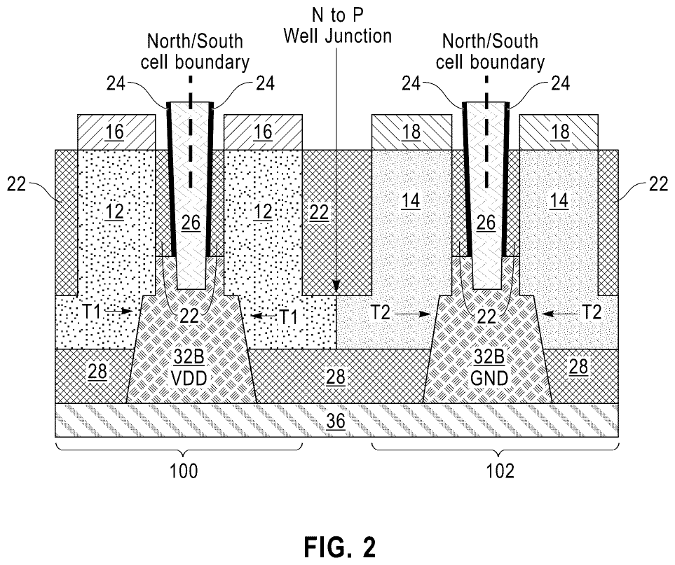

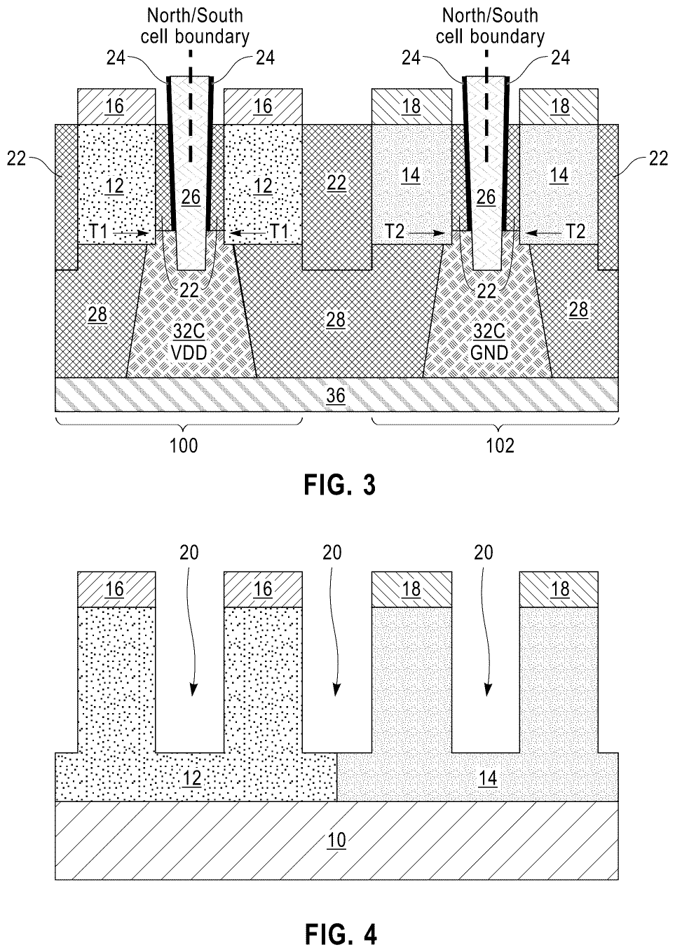

In the present application, semiconductor devices such as illustrated in FIGS. 1-3 are provided that include a conductor structure (including conductor contact pillar 26) located in a shallow trench isolation structure 22 that is positioned between two field effect transistors of a same conductivity type (i.e., either the two pFETs 16 or the two nFETs 18 shown in FIGS. 1-3), the conductor structure (including conductor contact pillar 26) is electrically connected to a backside contact structure (e.g., backside contact structure 32A shown in FIG. 1, backside contact structure 32B shown in FIG. 2 and backside contact structure 32C shown in FIG. 3), and the backside contact structure is electrically connected to at least one well region (i.e., n-well region 12 or p-well region 14) that straddles a sidewall of the backside contact structure. The conductor structure including the conductor contact pillar 26 can be a via structure, a via bar structure or a rail-like structure. In the present application, local well taps are provided and are defined by the area of contact between the backside contact structure and the at least one well region. In the present application, the resistive path shrinks to the well region (either the n-well or p-well) and thus the efficiency of the well tap is enhanced. Also, and in the present application, the entire length of the well region is at iso-potential. Holding the well regions at iso-potential assures no change in bulk leakage across a circuit row. The local wall taps of the present application relax and, in some cases, even eliminate guarding ground-rules that exist with conventional well taps.

Referring first to FIG. 1, there is illustrated an exemplary semiconductor device in accordance with an embodiment of the present application. The exemplary semiconductor device illustrated in FIG. 1 includes a pFET device region 100 and an nFET device region 102 that are located laterally adjacent to each other. Although the illustrated embodiment shows both a pFET device region 100 and an nFET device region 102, the present application works when only a single device region, either the pFET device region 100 or the nFET device region 102, is present. In the illustrated embodiment shown in FIG. 1, the pFET device region 100 includes a plurality of pFETs 16 (two of which are shown in FIG. 1 by way of an example) located on a surface of an n-well region 12, and the nFET device region 102 includes a plurality of pFETs 18 (two of which are shown in FIG. 1 by way of an example) located on a surface of a p-well region 14. In this embodiment, the n-well region 12 and the p-well region 14 are in direct physical contact with each other and, as such, an n-well-to-p-well junction exists. Shallow trench isolation structures 22 are also present in the exemplary semiconductor device shown in FIG. 1. In the present application, some of the shallow trench isolation regions 22 are used to separate like conductivity type FETs (i.e., nFETs from nFETs, and/or pFETs from pFETS) from each other, while other shallow trench isolation regions 22 can be used to separate different conductivity type FETs (i.e., nFETs from pFETs) from each other. In this embodiment, the substrate that was removed was thicker than the depth of the shallow trench isolation structures 22.

The exemplary semiconductor device shown in FIG. 1 also includes a conductor structure located in both the pFET device region 100 and in the nFET device region 102; that is a first conductor structure can be present in the pFET device region 100 and a second conductor structure can be present in the nFET device region 102. Each conductor structure includes a conductor contact pillar 26 and a liner 24; liner 24 can also be referred to as conductor contact pillar liner. In this embodiment, liner 24 is present along an entirety of the sidewall of the conductor contact pillar 26. Each conductor structure extends from the frontside of the exemplary semiconductor device to the backside of the exemplary semiconductor device, and each conductor structure is present in a shallow trench isolation structure 22 that is used to separate like conductivity type FETs (i.e., nFETs from nFETs, and/or pFETs from pFETS) from each other. Although not illustrated in FIG. 1 (or in any of the remaining drawings of the present application), each conductor structure (especially, the conductor contact pillar 26) would be electrically connected to a source/drain region of one of the transistors that is present in the particular device region.

The exemplary semiconductor device shown in FIG. 1 also includes a backside ILD layer 28 located beneath each of the n-well region 12 and the p-well region 14 and a backside contact structure 32A is present in each of the pFET device region 100 and in the nFET device region 102. In the exemplary embodiment illustrated in FIG. 1, each backside contact structure 32A has a pyramidal shape in which the bottom portion of the pyramid has a first critical dimension, i.e., first width, and the top portion of the pyramid has a second critical dimension, i.e., second width, which is less than the first critical dimension, i.e., first width. In this embodiment, a first surface of the backside contact structure 32A is in electrical contact with a bottom surface of at least the conductor contact pillar 26 of the conductor structure, while a second surface opposite the first surface is in electrical contact with a backside power distribution network structure 36. In FIG. 1, VDD is shown to illustrate a positive supply voltage for the semiconductor device, while GND refers to “ground”, i.e., zero potential of a common wire for power and signal in the semiconductor device.

The backside power distribution network structure (which can also be referred to a backside back-end-of-the-line (BEOL) structure) 36 is composed of an interconnect dielectric region having backside metal wiring embedded therein. The interconnect dielectric region includes one or more interconnect dielectric material layers. The interconnect dielectric material layers can be composed of an interlayer dielectric material. The backside metal wiring which can be in the form of metal lines, metal vias, metal via/metal line combinations or any combinations thereof is composed of an electrically conductive metal or an electrically conductive metal alloy. Exemplary electrically conductive metals include, but are not limited to, Cu, W, Al, Co, or Ru. An exemplary electrically conductive metal alloy is a Cu—Al alloy. The backside power distribution network structure 36 can be formed utilizing any well-known BEOL process including a damascene process or a subtractive metal etch process.

In the present application, each of the backside contact structures 32A is embedded in the backside ILD layer 28 and one of the well regions (i.e., the n-well region 12 or the p-well region 14). In the present application, each backside contact structure 32A makes a sidewall connection to like well regions that straddle the backside contact structure 32A. The direct connection between the backside contact structure 32A and straddling well regions produces the backside local well tap in accordance with the present application. In FIG. 1, T1 is used to designate the location of the n-well tap, while T2 is used to designate the location of the p-well tap.

Notably, FIG. 1 illustrates a semiconductor device in accordance with an embodiment of the present application. The semiconductor device illustrated in FIG. 1 includes two transistors of a first conductivity type (i.e., pFETs 16 or nFETs 18) located on a surface of a well region (i.e., n-well region 12 or p-well region 14) of a second conductivity type that differs from the first conductivity type, shallow trench isolation structure 22 is located between the two transistors of the first conductivity type, conductor structure is located in the shallow trench isolation structure 22 and includes at least a conductor contact pillar 26, and backside contact structure 32A is electrically connected to a bottom surface of the conductor contact pillar 26 and is in direct contact with a sidewall of the well region (i.e., n-well region 12 or p-well region 14) that is located beneath each of the transistors of the first conductivity type (i.e., pFETs 16 or nFETs 18). In illustrated embodiment of FIG. 1, local well taps (i.e., T1 or T2) are provided and are defined by the area of contact between the backside contact structure 32A and the well region (i.e., n-well region 12 or p-well region 14). In the present application, the resistive path shrinks to the well region (either the n-well 12 or p-well region 14) and thus the efficiency of the well tap is enhanced. Also, and in the present application, the entire length of the well region (i.e., n-well region 12 or p-well region 14) is at iso-potential. The local wall taps of the present application and as found in FIG. 1 relax and, in some cases, even eliminate guarding ground-rules that exist with conventional well taps. With local well taps T1 and T2, the RC delay from the power supply to any junction capacitance to the well (e.g., drain/well capacitance) is reduced. This allows for the junction capacitance to act as a decoupling capacitor against higher frequency conductor structure noise.

In some embodiments of the present application, the shallow trench isolation structure 22 has a depth that is shallower than a depth of the well region (i.e., n-well region 12 or p-well region 14). This aspect of the present application results in an n-well/p-well diode, which can be used for various non-logic devices such as ESD and bipolar devices.

In some embodiments of the present application, the semiconductor device of this embodiment further includes backside power distribution network structure 36 in electrical contact with the backside contact structure 32A. This aspect of the present application allows for backside power delivery from the backside of the device to the frontside of the device. Backside power delivery offers several advantages, including increased logic density and improved power and performance (better signal integrity, reduced noise and improved overall chip performance).

In some embodiments of the present application, the conductor structure further includes a liner 24 present along an entirety of a sidewall of the conductor contact pillar 26. The liner 24 provides isolation to the conductor contact pillar 26.

In some embodiments of the present application, the backside contact structure 32A has a shape of a pyramid having a top portion electrically connected to the bottom surface of the conductor contact pillar 26, and a bottom portion opposite the top portion, in which the bottom portion of the pyramid has a first critical dimension and the top portion of the pyramid has a second critical dimension less than the first critical dimension. This aspect of the present application splits the total conductor structure height between a frontside etch and a backside etch, thus allowing for a high aspect ratio with less overall taper angle to the via sidewall.

In some embodiments of the present application, the backside contact structure 32A is composed of a contact conductor material, and the contact conductor material is in direct physical contact with the sidewall of the well region (i.e., n-well region 12 or p-well region 14) and with the bottom surface of the conductor contact pillar 26.

In some embodiments of the present application, the backside contact structure 32A is composed of a silicide, and the silicide is in direct physical contact with the sidewall of the well region (i.e., n-well region 12 or p-well region 14). The use of a silicide material can reduce contact resistance between the conductor structure and the well region.

Referring now to FIG. 2, there is illustrated another exemplary semiconductor device in accordance with another embodiment of the present application. The another exemplary semiconductor device illustrated in FIG. 2 is similar to the exemplary semiconductor device illustrated in FIG. 1 except that backside contact structures 32A are replaced by backside contact structures 32B; backside contact structures 32B can be referred to as wrap-around backside contact structures. The backside contact structures 32B have a pyramidal shape in which the bottom portion of the pyramid has a first critical dimension, i.e., first width, and the top portion of the pyramid has a second critical dimension, i.e., second width, which is less than the first critical dimension, i.e., first width. Also, the upper portion of the backside contact structures 32B wraps arounds the conductor structure, and forms not only an electrical connection with, a bottom surface of the conductor contact pillar 26, but an electrical connection with a sidewall of the conductor contact pillar 26. Since the backside contact structure 32B wraps around a bottom portion of the conductor structure, the liner 24 does not extend the full length of the conductor contact pillar 26. Also, and in this embodiment, T1 and T2 have a greater surface area as compared to T1 and T2 in the exemplary embodiment illustrated in FIG. 1. Also, the backside contact structures 32B of the exemplary semiconductor device shown in FIG. 2 lower the contact resistance of the device as compared to the exemplary semiconductor device shown in FIG. 1 in which non-wrap-around backside contact structures 32A are used.

Notably, FIG. 2 illustrates a semiconductor device in accordance with another embodiment of the present application. The semiconductor device illustrated in FIG. 2 includes two transistors of a first conductivity type (i.e., pFETs 16 or nFETs 18) located on a surface of a well region (i.e., n-well region 12 or p-well region 14) of a second conductivity type that differs from the first conductivity type, shallow trench isolation structure 22 is located between the two transistors of the first conductivity type, conductor structure is located in the shallow trench isolation structure 22 and includes at least a conductor contact pillar 26, and backside contact structure 32B electrically connected to both a sidewall and a bottom surface of the conductor contact pillar 26 of the conductor structure and in direct contact with a sidewall of the well region (i.e., n-well region 12 or p-well region 14) that is located beneath each of the transistors of the first conductivity type (i.e., pFETs 16 or nFET 18). In the exemplary embodiment of FIG. 2, local well taps (i.e., T1 or T2) are provided and are defined by the area of contact between the backside contact structure 32B and the well region. In the present application, the resistive path shrinks to the well region (either the n-well or p-well) and thus the efficiency of the well tap is enhanced. Also, and in the present application, the entire length of the well region is at iso-potential. The local wall taps (i.e., T1 or T2) of the present application which are exemplified in FIG. 2 relax and, in some cases, even eliminate guarding ground-rules that exist with conventional well taps. The backside contact structure 32B is a backside wrap-around contact which has increased contact area with the conductor contact pillar 26. The increased contact area from the wrap-around backside contact structure (i.e., the backside contact structure 32B) reduces the total vertical resistance from the bottom of the backside contact structure 32B to the top of the conductor structure.

In some embodiments of the present application, the shallow trench isolation structure 22 has a depth that is shallower than a depth of the well region (i.e., n-well region 12 or p-well region 14). This aspect of the present application results in an n-well/p-well diode, which can be used for various non-logic devices such as ESD and bipolar devices.

In some embodiments of the present application, the semiconductor device of this embodiment further includes backside power distribution network structure 36 in electrical contact with the backside contact structure 32B. This aspect of the present application allows for backside power delivery from the backside of the device to the frontside of the device. Backside power delivery offers several advantages, including increased logic density and improved power and performance (better signal integrity, reduced noise and improved overall chip performance).

In some embodiments of the present application, the conductor structure further includes liner 24 present along an upper portion of the sidewall of the conductor contact pillar 26. The liner 24 provides isolation to the conductor contact pillar 26.

In some embodiments of the present application, the backside contact structure 32B has a shape of a pyramid having a top portion electrically connected to both the sidewall and the bottom surface of the conductor contact pillar 26, and a bottom portion opposite the top portion, wherein the bottom portion of the pyramid has a first critical dimension and the top portion of the pyramid has a second critical dimension less than the first critical dimension. This aspect of the present application splits the total conductor structure height between a frontside etch and a backside etch, thus allowing for a high aspect ratio with less overall taper angle to the via sidewall.

In some embodiments of the present application, the backside contact structure 32B is composed of a contact conductor material, and the contact conductor material is in direct physical contact with the sidewall of the well region (i.e., n-well region 12 or p-well region 14) and with both the sidewall and the bottom surface of the conductor contact pillar 26.

In some embodiments of the present application, the backside contact structure 32B is composed of a silicide, and the silicide is in direct physical contact with the sidewall of the well region (i.e., n-well region 12 or p-well region 14). The use of a silicide material can reduce contact resistance between the conductor structure and the well region.

Referring now to FIG. 3, there is illustrated a yet another exemplary semiconductor device in accordance with yet another embodiment of the present application. The exemplary semiconductor device illustrated in FIG. 3 includes like elements as shown in FIG. 1 except that the backside contact structures 32A are replaced by backside contact structures 32C which can also be referred to as wrap-around backside contact structures. Also, and unlike the exemplary semiconductor device illustrated in FIG. 1, the exemplary semiconductor device illustrated in FIG. 3 does not include any n-well-to-p-well junction. Notably, and as shown in FIG. 3, each of the well regions (i.e., n-well regions 12 and p-well regions 14) exists as an isolated island embedded in a shallow trench isolation structure 22. In this embodiment, the substrate that was removed was thinner than the depth of the shallow trench isolation structures 22. In this embodiment, the backside contact structures 32C is also pyramidal in shape in which the bottom portion of the pyramid has a first critical dimension, i.e., first width, and the top portion of the pyramid has a second critical dimension, i.e., second width, which is less than the first critical dimension, i.e., first width. Also, the upper portion of the backside contact structures 32C wraps arounds the conductor structure, and forms not only an electrical connection with, a bottom surface of the conductor contact pillar 26, but an electrical connection with a sidewall of the conductor contact pillar 26. Since the backside contact structure 32C wraps around a bottom portion of the conductor structure, the liner 24 does not extend the full length of the conductor contact pillar 26. In this embodiment, the backside contact structure 32C is in direct contact with, not only a sidewall of adjacent well regions, but also a bottommost surface of the adjacent well regions as shown in FIG. 3. In this embodiment, T1 and T2 have a greater surface area as compared to T1 and T2 in the exemplary embodiment illustrated in FIG. 1. Also, the backside contact structures 32C (i.e., wrap-around backside contact structures) of the exemplary semiconductor device shown in FIG. 3 lower the contact resistance of the device as compared to the exemplary semiconductor device shown in FIG. 1 in which non-wrap-around backside contact structures 32A are used.

Notably, FIG. 3 illustrates a semiconductor device in accordance with a yet another embodiment of the present application. The semiconductor device illustrated in FIG. 3 includes two transistors of a first conductivity type (i.e., pFETs 16 or nFETs 18) located on a surface of a well region (i.e., n-well region 12 or p-well region 14) of a second conductivity type that differs from the first conductivity type, shallow trench isolation structure 22 is located between the two transistors of the first conductivity type, conductor structure is located in the shallow trench isolation structure 22 and includes at least a conductor contact pillar 26, and backside contact structure 32C electrically connected to both a sidewall and a bottom surface of the conductor contact pillar 26 of the conductor structure and in direct contact with both a sidewall and a bottom surface of the well region (i.e., n-well region 12 or p-well region 14) that is located beneath each of the transistors of the first conductivity type (i.e., pFETs 16 or nFET 18). In this exemplary embodiment of the present application, local well taps (i.e., T1 or T2) are provided and are defined by the area of contact between the backside contact structure 32C and the well region. In the present application, the resistive path shrinks to the well region (either the n-well or p-well) and thus the efficiency of the well tap is enhanced. Also, and in the present application, the entire length of the well region is at iso-potential. The local wall taps (i.e., T1 or T2) of the present application and as exemplified in FIG. 3 relax and, in some cases, even eliminate guarding ground-rules that exist with conventional well taps. The backside contact structure 32C is a backside wrap-around contact which has increased contact area with the conductor contact pillar 26 as well as with the well region (i.e., n-well region 12 or p-well region 14). The increased contact area from the wrap-around backside contact structure (i.e., the backside contact structure 32C) reduces the total vertical resistance from the bottom of the backside contact structure 32C to the top of the conductor structure.

In some embodiments of the present application, the semiconductor device of this embodiment further includes backside power distribution network structure 36 in electrical contact with the backside contact structure 32C. This aspect of the present application allows for backside power delivery from the backside of the device to the frontside of the device. Backside power delivery offers several advantages, including increased logic density and improved power and performance (better signal integrity, reduced noise and improved overall chip performance.

In some embodiments of the present application, the conductor structure further includes liner 24 present along an upper portion of the sidewall of the conductor contact pillar 26. The liner 24 provides isolation to the conductor contact pillar 26.

In some embodiments of the present application, the backside contact structure 32C has a shape of a pyramid having a top portion electrically connected to both the sidewall and the bottom surface of the conductor contact pillar 26, and a bottom portion opposite the top portion, wherein the bottom portion of the pyramid has a first critical dimension and the top portion of the pyramid has a second critical dimension less than the first critical dimension. This aspect of the present application splits the total conductor structure height between a frontside etch and a backside etch, thus allowing for a high aspect ratio with less overall taper angle to the via sidewall.

In some embodiments of the present application, the backside contact structure 32C is composed of a contact conductor material, and the contact conductor material is in direct physical contact with the sidewall of the well region (i.e., n-well region 12 or p-well region 14) and with both the sidewall and the bottom surface of the conductor contact pillar 26.

In some embodiments of the present application, the backside contact structure 32C is composed of a silicide, and the silicide is in direct physical contact with the sidewall and bottom surface of the well region (i.e., n-well region 12 or p-well region 14). The use of a silicide material can reduce contact resistance between the conductor structure and the well region.

In a further embodiment of the present application, the semiconductor device (as shown in FIGS. 1-3) includes pFET device region 100 including two pFETs 16 located on a surface of n-well region 12, a first shallow trench isolation structure (i.e., shallow trench isolation structure 22 present in the pFET device region 100) located between the two pFETs 16, a first conductor structure (i.e., the conductor structure on the left hand side of the drawings) located in the first shallow trench isolation structure and including at least a first conductor contact pillar (i.e., conductor contact pillar 26 on the left hand side of the drawings), and a first backside contact structure (i.e., backside contact structure 32A, 32B or 32C located on the left hand side of the drawings) electrically connected to at least a bottom surface of the first conductor contact pillar of the first conductor structure and in direct contact with a sidewall of the n-well region 12. The semiconductor device of this further embodiment also includes an nFET device region 102 located adjacent to the pFET device region 100 and including two nFETs 18 located on a surface of p-well region 14, a second shallow trench isolation structure (i.e., shallow trench isolation structure 22 present in the pFET device region 100) located between the nFETs 18, a second conductor structure (i.e., the conductor structure on the right hand side of the drawings) located in the second shallow trench isolation structure and including at least a second conductor contact pillar (i.e., the conductor contact pillar 26 on the left hand side of the drawings), and a second backside contact structure (i.e., backside contact structure 32A, 32B or 32C located on the right hand side of the drawings) electrically connected to at least a bottom surface of the second conductor contact pillar of the second conductor structure and in direct contact with a sidewall of the p-well region 14. In this exemplary embodiment of the present application, local well taps (i.e., T1 and T2) are provided and are defined by the area of contact between the backside contact structure 32C and the well region. In the present application, the resistive path shrinks to the well region (either the n-well or p-well) and thus the efficiency of the well tap is enhanced. Also, and in the present application, the entire length of the well region is at iso-potential. The local wall taps (i.e., T1 and T2) of the present application and as exemplified in FIGS. 1,2 and 3 relax and, in some cases, even eliminate guarding ground-rules that exist with conventional well taps.

In some embodiments of the present application, the n-well region 12 and the p-well region 14 are in contact with each other under a third shallow trench isolation structure that separates the pFET device region 100 from the nFET device region 102.

In some embodiments of the present application, the n-well region 12 and the p-well region 14 are physically separated from each other.

In some embodiments of the present application, each of the first backside contact structure (32A or 32B or 32C) and the second backside contact structure (32A or 32B or 32C) is a wrap-around backside contact structure. Backside wrap-around contact provide increased contact area with the conductor contact pillar 26 as well as with the well region (i.e., n-well region 12 or p-well region 14). The increased contact area from the wrap-around backside contact structure reduces the total vertical resistance from the bottom of the backside contact structure to the top of the conductor structure.

In some embodiments, the semiconductor device further includes backside power distribution network structure 36 in electrical contact with the first backside contact structure (32A or 32B or 32C) and with the second backside contact structure (32A or 32B or 32C). This aspect of the present application allows for backside power delivery from the backside of the device to the frontside of the device. Backside power delivery offers several advantages, including increased logic density and improved power and performance (better signal integrity, reduced noise and improved overall chip performance.

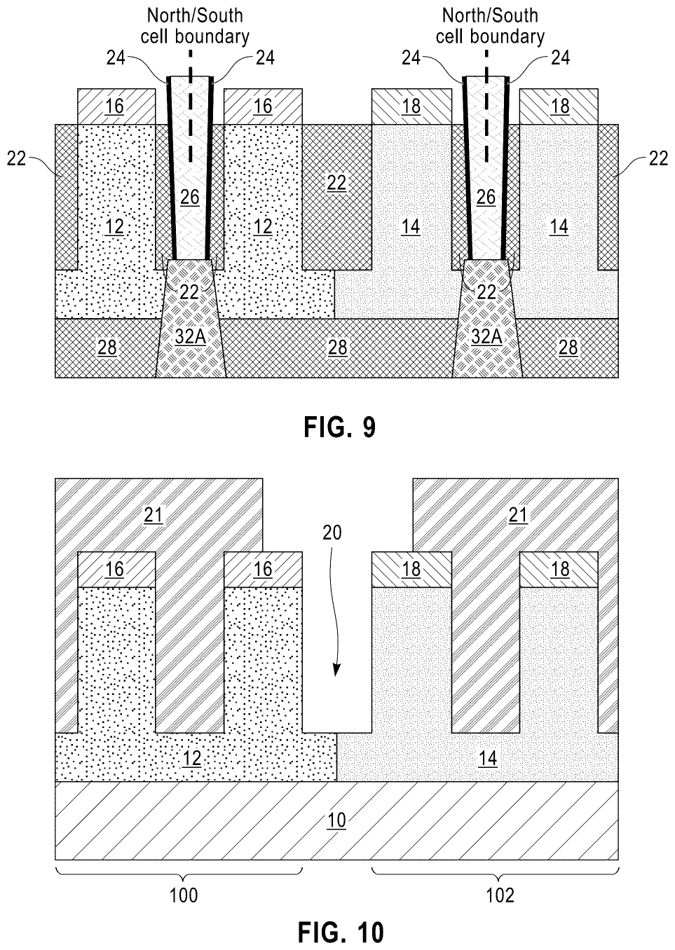

The various elements illustrated in FIGS. 1-3 will be described in greater detail herein below in reference to FIGS. 4-21. With respect to FIGS. 4-21, FIGS. 4-9 illustrate a processing flow for forming an exemplary semiconductor device as shown, for example, in FIG. 1 (or with a slight modification for forming an exemplary semiconductor device as shown, for example, in FIG. 2). FIGS. 10-17 illustrate another processing flow for forming an exemplary semiconductor device as shown, for example, in FIG. 1 (or with a slight modification for forming an exemplary semiconductor device as shown, for example, in FIG. 2). FIGS. 18-21 illustrate a yet other processing flow for forming an exemplary semiconductor device as shown, for example, in FIG. 1 (or with a slight modification for forming an exemplary semiconductor device as shown, for example, in FIG. 2).

Referring now to FIG. 4, there is illustrated an exemplary semiconductor structure (i.e., an initial structure) that can be employed in accordance with the present application. The exemplary structure illustrated in FIG. 4 includes a semiconductor base layer 10, an n-well region 12 and a p-well region 14 located laterally adjacent to each other and on the semiconductor base layer 10, pFETs 16 located on the n-well region 12, nFETs 18 located on the p-well region 14, and shallow trench isolation openings 20 located in both the n-well region 12 and the p-well region 14. It noted that although both pFETs 16 and nFETs 18 are described and illustrated, the present application works when only one type of conductivity device (i.e., pFET 16 or nFET 18) is present.

The semiconductor base layer 10 can be composed of a semiconductor material as defined above. In one example, the semiconductor base layer 10 is composed of Si. The n-well region 12 is composed of a semiconductor material (e.g., Si) and an n-type dopant as defined above. The concentration of n-type dopant within the n-well region 12 is typically from 1×10¹⁷ atoms/cm³ to 1×10¹⁹ atoms/cm³. The p-well region 14 is composed of a semiconductor material (e.g., Si) and a p-type dopant as defined above. The concentration of p-type dopant within the p-well region 14 is typically from 1×10¹⁷ atoms/cm³ to 1×10¹⁹ atoms/cm³. In some embodiments (not shown) an etch stop layer is present between the semiconductor base layer 10 and each of the overlying well regions (i.e., n-well region 12 and p-well region 14). In some embodiments, the etch stop layer is composed of a dielectric material such as, for example, silicon dioxide and/or boron nitride. In other embodiments, the etch stop layer is composed of a semiconductor material that is compositionally different from the semiconductor material that provides the semiconductor base layer 10 and both well regions (i.e., n-well region 12 and p-well region 14). The semiconductor material that provides the n-well region 12 is typically a compositionally same semiconductor material as that which provides the p-well region 14.

The well regions (i.e., n-well region 12 and p-well region 14) are formed utilizing techniques well known to those skilled in the art. In one example, the well regions (i.e., n-well region 12 and p-well region 14) can be formed by first providing a p-semiconductor material layer. A patterned masking layer is then formed over at least one area of the p-semiconductor material layer, leaving at least one other area of the p-semiconductor material layer physically exposed. An n-well implant is then performed in the area of the p-semiconductor material layer that does not include the patterned masking layer. A drive-in anneal can follow the n-well implant to form the n-well region 12. The patterned masking layer is then removed, and another patterned masking layer is formed on the n-well region. A p-well implant is then performed in the area of the p-semiconductor material layer that does not include the another patterned masking layer. A drive-in anneal can follow the p-well implant to form the p-well region 14. In some embodiments, a single drive-in anneal can be performed after both well implants have been performed. The another patterned masking layer is removed after at least the p-well implant step.

The pFETs 16 and the nFETs 18 include a semiconductor channel region, source/drain region, and a gate structure, each of which has been described above. The pFETs 16 and the nFETs 18 can also include a gate dielectric spacer located adjacent to the gate structure and, an optional gate hard mask cap located on top of the gate structure. When nanosheet transistors are formed, inner dielectric spacers can be present beneath each semiconductor channel material nanosheet of a vertical stack of semiconductor channel material nanosheets. The gate dielectric spacer, gate hard mask cap and inner dielectric spacer are not separately illustrated in the drawings of the present application. The pFETs 16 and the nFETs 18 can be formed utilizing any conventional transistor fabrication process including, for example, a nanosheet transistor fabrication process. The pFETs 16 and the nFETs 18 can be formed at the same time, or block mask technology can be used such that one of the conductivity type transistors is formed before the other conductivity type transistors. It is noted that is some embodiments, the fabrication of the pFETs 16 and the nFETs 18 can take place after forming the shallow trench isolation structures 22 into each of the well regions.

In the illustrated embodiment, and after forming the pFETs 16 and nFETs 18, shallow trench isolation openings 20 are formed into each of the well regions (i.e., n-well region 12 and p-well region 14), one of the shallow trench isolation openings 20 can also be formed in an area in which the n-well region 12 contacts the p-well region 14. The shallow trench isolation openings 20 can be formed lithography and an etching process that is selective in removing the semiconductor material that provides each of the well regions (i.e., n-well region 12 and p-well region 14). In one example, the etching process can include a reactive ion etch (RIE). The etch used in forming the shallow trench isolation openings 20 stops on a sub-surface of each of the well regions (i.e., n-well region 12 and p-well region 14). The term “sub-surface” denotes a surface of a material layer/structure that is located between a topmost surface and a bottommost surface of the material layer/structure.

Referring now to FIG. 5, there is illustrated the exemplary semiconductor structure of FIG. 4 after forming a shallow trench isolation structure 22 in each of the shallow trench isolation openings 20. Each shallow trench isolation structure 22 can include a trench dielectric liner and a trench dielectric material. The trench dielectric liner includes a trench dielectric liner material such as, for example, silicon nitride. The trench dielectric material is composed of any trench dielectric such as, for example, silicon dioxide. The trench dielectric liner is present along a sidewall and a bottom wall of the trench dielectric material. In some embodiments, each shallow trench isolation structure 22 can have a topmost surface that is substantially coplanar with a topmost surface of the both the n-well region 12 and the p-well region 14. In other embodiments, each shallow trench isolation structure 22 can have a topmost surface that is vertically offset (i.e., higher or lower) than a topmost surface of both the n-well region 12 and the p-well region 14. Each shallow trench isolation structure 22 can be formed by deposition of a layer of a trench dielectric liner material in each of the shallow trench isolation openings 20. The deposition of the layer of trench dielectric liner material includes, but is not limited to, chemical vapor deposition (CVD), plasma enhanced chemical vapor deposition (PECVD), or physical vapor deposition (PVD). The layer of trench dielectric liner material lines a sidewall and a bottom wall of the shallow trench isolation openings 20, but does not fill in an entire volume of each of the shallow trench isolation opening 20. A layer of trench dielectric material is then formed on the layer of trench dielectric liner material by a deposition process such as, for example, CVD, PECVD or PVD. Next, a combination of a planarization process such as, for example, chemical mechanical, and an etch back process are used to complete the formation of the shallow trench isolation structures 22. In the illustrated embodiment, each shallow trench isolation structure 22 has a depth that is shallower than a depth of the well region.

Although not shown in the drawings of the present application, a frontside ILD layer can be formed after fabrication of the shallow trench isolation structures 22 so as to embed the source/drain regions of each of the pFETs 16 and nFETs 18. The frontside ILD layer is composed of ILD material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. The frontside ILD layer can be formed by a deposition process such as, for example, CVD, PECVD or spin-on coating. A planarization process such as, for example, chemical mechanical polishing (CMP) can follow the deposition of the ILD material that provides the frontside ILD layer.

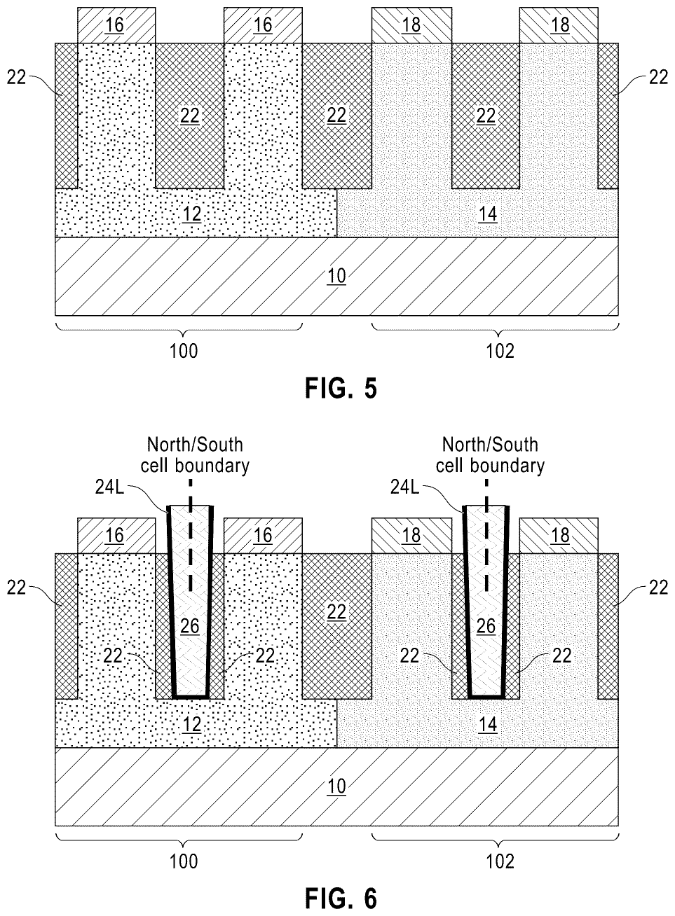

Referring now to FIG. 6, there is illustrated the exemplary semiconductor structure of FIG. 5 after forming a conductor structure in each of the pFET device region 100 and nFET device region 102. The conductor structure is formed into the frontside ILD layer and through the shallow trench isolation structure 20 that separates like conductivity type transistors from each other. Each conductor structure lands on the sub-surface of the well region (i.e., n-well region 12 or p-well region 14) as is shown in FIG. 6. At this stage of the processing flow, the conductor structure includes a liner material layer 24L and a conductor contact pillar 26.

The liner material layer 24L is located along a sidewall and a bottom wall of the conductor contact pillar 26. The liner material layer 24L is composed of a liner material. In some embodiments, liner material layer 24L can be an adhesion metal material such as, for example, Ti, Ta, TiN, TiN or any combination thereof. In such embodiments, the adhesion metal material can be formed by a deposition process such, as for example, CVD, PECVD, atomic layer deposition (ALD) or PVD. In some embodiments, liner material layer 24L can be composed of a silicide such as, for example, as TiSi, NiSi, NiPtSi or any combination thereof. In such embodiments, the silicide is formed utilizing a silicidation process that is well known to those skilled in the art. In yet other embodiments, liner material layer 24L includes a combination of an adhesion metal materiel and a silicide. The conductor contact pillar 26 is composed of a contact conductor material such, as for example, W, Cu, Al, Co, Ru, Mo, Os, Ir, Rh, or an alloy thereof. The contact conductor material can be formed by any suitable deposition method such as, for example, CVD, ALD, PVD or plating.

Each conductor structure can be formed by a metallization process that includes forming (by photolithography and etching) a conductor structure opening into the frontside ILD layer and through the shallow trench isolation structure 22 that separates like conductivity type transistors from each other. The metallization process continues by forming the liner material layer 24L along the sidewall and bottom wall of the conductor structure opening, and then forming the contact conductor material on the liner material layer 24L. Following the forming of the contact conductor material, a planarization process (such, for example, CMP) is used to remove the contact conductor material and the liner material layer 24L that are present outside the conductor structure opening.

After forming the conductor structure, additional frontside processing not shown in the drawings can be performed to complete the processing of the frontside of the exemplary semiconductor structure. The additional frontside processing can include forming a middle-of-the-line (MOL) level that includes frontside contact structures present therein. The frontside contact structures can include, for example, frontside gate contact structures, frontside source/drain contact structures and a frontside source/drain-to-conductor structure contact structure which electrically connects the conductor contact pillar 26 to one of the source/drain regions of one of the like conductivity type transistors (i.e., pFETs 16 or nFETs 18). The additional frontside processing can further include forming a frontside back-end-of-the-line (BEOL) structure above the MOL level. The frontside BEOL structure can include frontside metal wires embedded in one or more ILD layers. The frontside metal wires can be configured for signal delivery. The frontside BEOL structure is electrically connected to the nFETs 16 and pFETs 18 through the frontside contact structures that are present in the MOL level.

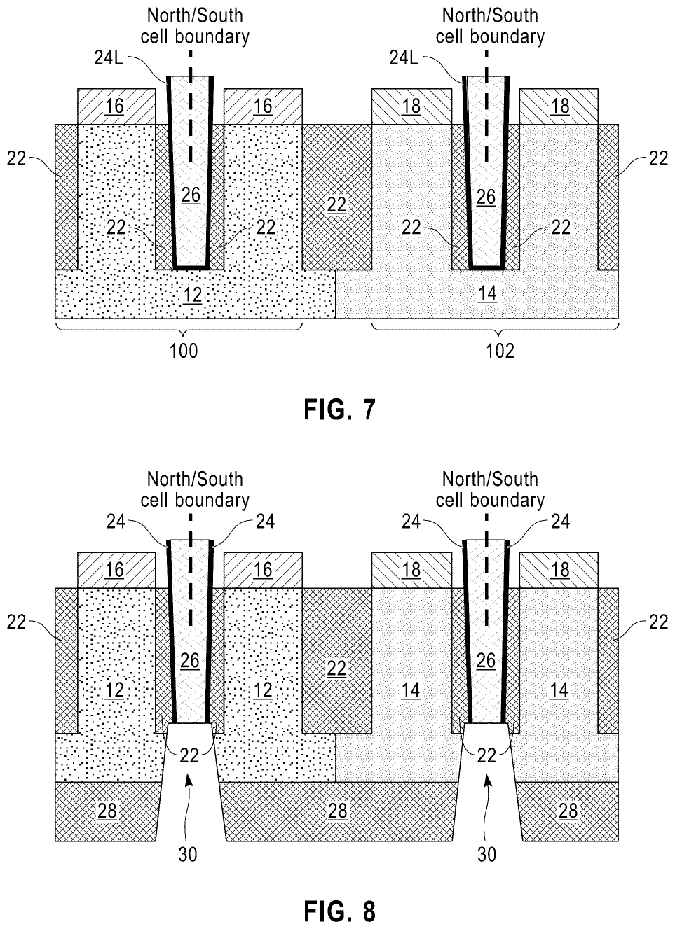

Referring now to FIG. 7, there is illustrated the exemplary semiconductor structure of FIG. 6 after removing the semiconductor base layer 10. The removal of the semiconductor base layer 10 reveals each of the n-well region 12 and the p-well region 14. The removal of the semiconductor base layer 10 begins by flipping the exemplary structure of FIG. 6 180° to physically expose a backside of the structure. For clarity, the flipping step is not shown in the drawings. Flipping can be performed by hand or by utilizing a mechanical means such as, for example, a robot arm. After flipping, the semiconductor base layer 10 is physically exposed and the physically exposed semiconductor base layer 10 is removed utilizing a material removal process that is selective in removing the semiconductor material that provides the semiconductor base layer 10. In embodiments in which an etch stop layer is present, the removal of the semiconductor base layer 10 reveals the etch stop layer, and thereafter the etch stop layer is removed to physically reveal each of the well regions (i.e., n-well region 12 and the p-well region 14).

Referring now to FIG. 8, there is illustrated the exemplary semiconductor structure of FIG. 7 after forming a backside ILD layer 28, and forming backside contact openings 30 that reveal a conductor contact pillar 26 of each conductor structure. The backside ILD layer 28 is composed of ILD material as defined above for the frontside ILD layer. The backside ILD layer 28 can be formed by a deposition process such as, for example, CVD, PECVD or spin-on coating. A planarization process such as, for example, CMP, can follow the deposition of the ILD material that provides the backside ILD layer 28. As is illustrated, the backside ILD layer 28 is formed in direct physically contact with both the n-well region 12 and the p-well region 14.

Each backside contact opening 30 can be formed by photolithography and etching. The etch used in providing each backside contact openings 30 can include RIE. In some embodiments, the etch removes portions of the backside ILD layer 28, the well region (i.e., n-well region 12 and the p-well region 14) and the liner material layer 24L that is present along the bottom surface of the conductor contact pillar 26 that are not protected by the patterned photoresist. The etch thus physically exposes the bottom surface of the conductor contact pillar 26 as shown in FIG. 8. The liner material layer 24L that remains along the sidewall of the conductor contact pillar 26 can now be referred to as liner 24.

In some embodiments (not shown in FIG. 8), an over etch can be used to remove the liner material layer 24L that is present on the bottom surface of the conductor contact pillar 26 as well as along a bottom portion of the sidewall of the conductor contact pillar 26; the over etch provides the wrap-around backside contact structures mentioned above in FIGS. 2 and 3. When an over etch is employed, the backside contact opening 30 physically exposes the bottom surface of the conductor contact pillar 26 as well as a bottom portion of the sidewall of the conductor contact pillar 26.

Referring now to FIG. 9, there is illustrated the exemplary semiconductor structure of FIG. 8 after forming a backside contact structure 32A in each of the backside contact openings 30. Each backside contact structure 32A is composed at least a contact conductor material as defined above In some embodiments, the contact conductor material is composed of a silicide such as for example, Ti, Ni, NiPt silicide. Each backside contact structure 32A can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In some embodiments (especially when the contact conductor material is other than a silicide), the contact liner can include a silicide. Each of the backside contact structure 32A can be formed by a metallization process which includes filling each backside contact opening 30 with at least a contact conductor material as exemplified above. The filling of each frontside contact opening can include a deposition process (such as, for example, CVD, PECVD, ALD or sputtering), followed by a planarization process.

As is shown, each backside contact structure 32A is in direct physical contact with at least the conductor contact pillar 26 of the conductor structure that is present in each of the pFET device region 100 and the nFET device region 102. Also, and in the present application, each backside contact structure 32A makes a sidewall connection to like well regions that straddle the backside contact structure 32A. The direct connection between the backside contact structure 32A and straddling well regions produces the backside local well taps (i.e., T1 and T2) as described above in respect to FIGS. 1, 2 and 3. In some embodiments, the contact conductor material of the backside contact structure 32A is direct physical contact with sidewall of the well region (n-well region 12 or p-well region 14) and with a bottom surface of the conductor contact pillar 26. In other embodiments and when a silicide is present in the backside contact structure 32A, the silicide is direct physical contact with the sidewall of the well region (n-well region 12 or p-well region 14). When over etching is employed, backside contact structure 32A can be replaced by a wrap-around backside contact structure (i.e. backside contact structure 32B or backside contact structure 32C shown in FIGS. 2 and 3, respectively).

Referring now to FIG. 10, there is illustrated the exemplary semiconductor structure of FIG. 4 after forming a mask 21 that reveals one of the shallow trench isolation openings 20. In this embodiment of the present application, the revealed shallow trench isolation opening 20 is the one that is located between the pFET 16 and nFET 18. Mask 21 can include one or more masking material layers. In one example, mask 21 is composed of an organic planarization layer (OPL). The mask 21 can be formed by deposition of a masking material, followed by photolithographic patterning of the as-deposited masking material.

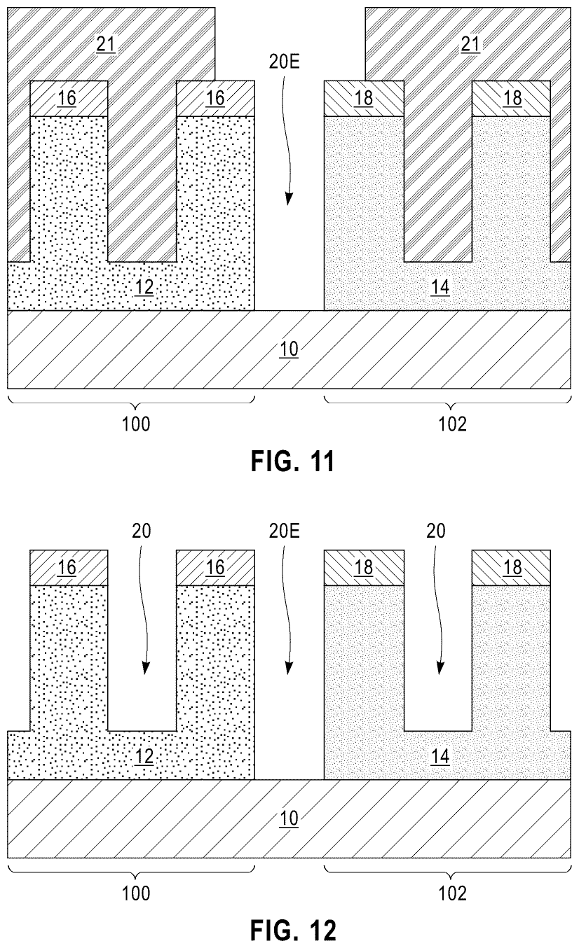

Referring now to FIG. 11, there is illustrated the exemplary semiconductor structure of FIG. 10 after extending the depth of the revealed shallow trench isolation opening 20 to provide an extended depth shallow trench isolation opening 20E between the pFET device region 100 and nFET device region 102. The extending the depth of the revealed the shallow trench isolation opening 20 includes an etching process that stops on a surface of the semiconductor base layer 10. The etch used in extending the depth of the revealed the shallow trench isolation opening 20 eliminates any junction between the n-well region 12 and the p-well region 14 as is shown in FIG. 11.

Referring now to FIG. 12, there is illustrated the exemplary semiconductor structure of FIG. 11 after removing the mask 21. The mask 21 can be removed utilizing any material removal process that is selective in removing the mask 21 from the exemplary structure. In one example, an ashing process can be used in removing mask 21.

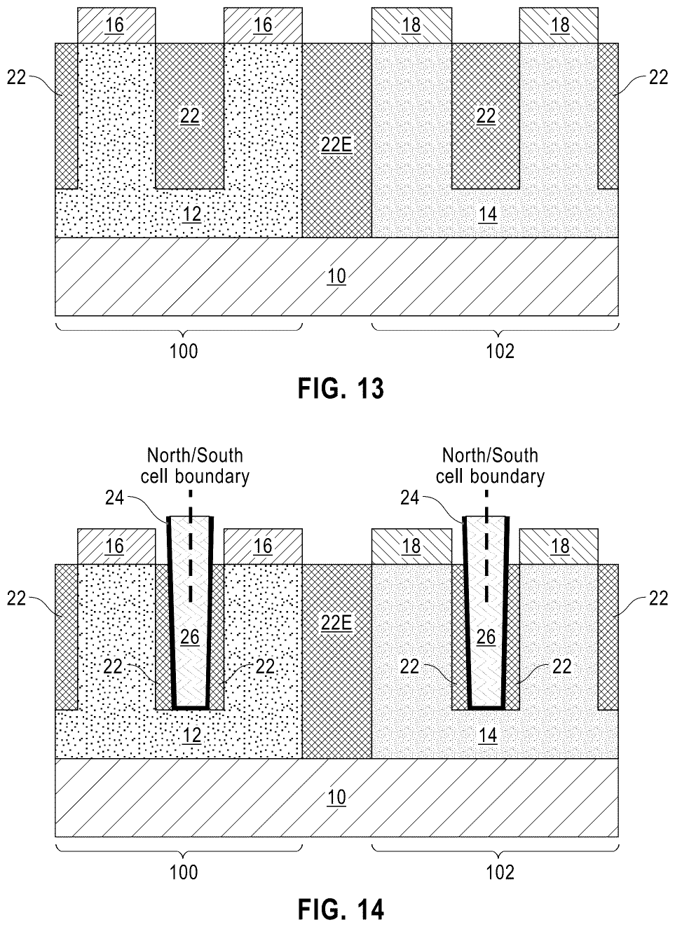

Referring now to FIG. 13, there is illustrated the exemplary semiconductor structure of FIG. 12 after forming a shallow trench isolation structure 22 in each shallow trench isolation opening 20, and an extended depth shallow trench isolation structure 22E in the extended depth shallow trench isolation opening 20E. The shallow trench isolation structure 22 and the extended depth shallow trench isolation structure 22E include a trench dielectric material and an optional trench dielectric liner, as defined above. The shallow trench isolation structure 22 and the extended depth shallow trench isolation structure 22E can be formed utilizing the same technique mentioned above in forming the shallow trench isolation structures 22 shown in FIG. 5. In this embodiment, each shallow trench isolation structure 22 lands on a sub-surface of one of the well regions (i.e., n-well region 12 or p-well region 14), while the extended depth shallow trench isolation structure 22E lands on a surface of the semiconductor base layer 10. In this embodiment, each shallow trench isolation structure 22 separates like conductivity type transistors from each other (i.e., nFET from nFET or pFET from pFET), while the extended depth shallow trench isolation structure 22E separates different conductivity type transistors from each other (i.e., nFET from pFET).

Referring now to FIG. 14, there is illustrated the exemplary semiconductor structure of FIG. 13 after forming a conductor structure in each of the pFET device region 100 and nFET device region 102. The conductor structure is formed into the frontside ILD layer and through the shallow trench isolation structure 22 that separates like conductivity type transistors from each other. Each conductor structure lands on the sub-surface of the well region (i.e., n-well region 12 or p-well region 14) as is shown in FIG. 14. At this stage of the processing flow, the conductor structure includes a liner material layer 24L and a conductor contact pillar 26, both as defined above in regard to the conductor structure shown in FIG. 6. The conductor structures shown in FIG. 14 can be formed utilizing the metallization process mentioned above for forming the conductor structures shown in FIG. 6. After forming the conductor structures, additional frontside processing as described above can be performed on the exemplary semiconductor structure shown in FIG. 14.

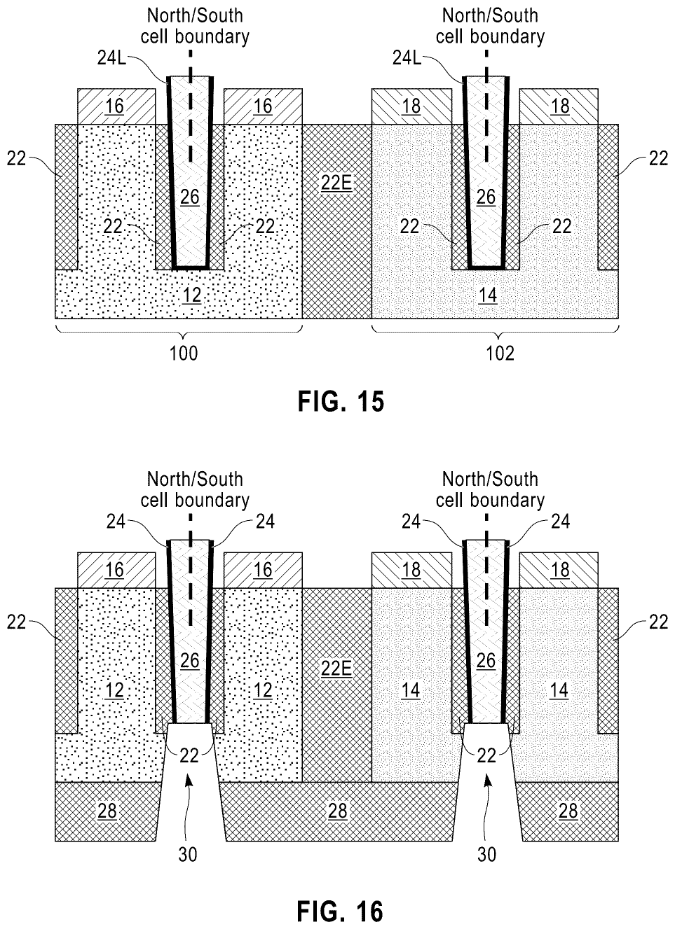

Referring now to FIG. 15, there is illustrated the exemplary semiconductor structure of FIG. 14 after removing the semiconductor base layer 10. The removal of the semiconductor base layer 10 reveals each of the n-well region 12 and the p-well region 14. The removal of the semiconductor base layer 10 in this embodiment is the same as described above in regarding to providing the exemplary semiconductor structure shown in FIG. 7. Note that if an etch stop layer is present, the etch stop layer is also removed to physically expose each of the well regions (i.e., n-well region 12 and the p-well region 14).

Referring now to FIG. 16, there is illustrated the exemplary semiconductor structure of FIG. 15 after forming a backside ILD layer 28, and forming backside contact openings 30 that reveal a conductor contact pillar 26 of each conductor structure. The backside ILD layer 28 used in this embodiment is the same as that mentioned above in forming the exemplary structure shown in FIG. 8. The forming of the backside contact openings 30 includes the technique mentioned above in forming the backside contact openings 30 shown in FIG. 8. The etch used in forming the backside contact openings 30 can include, in some embodiments, an over etch. When an over etch is performed, the backside contact opening 30 physically exposes the bottom surface of the conductor contact pillar 26 as well as along a bottom portion of the sidewall of the conductor contact pillar 26.

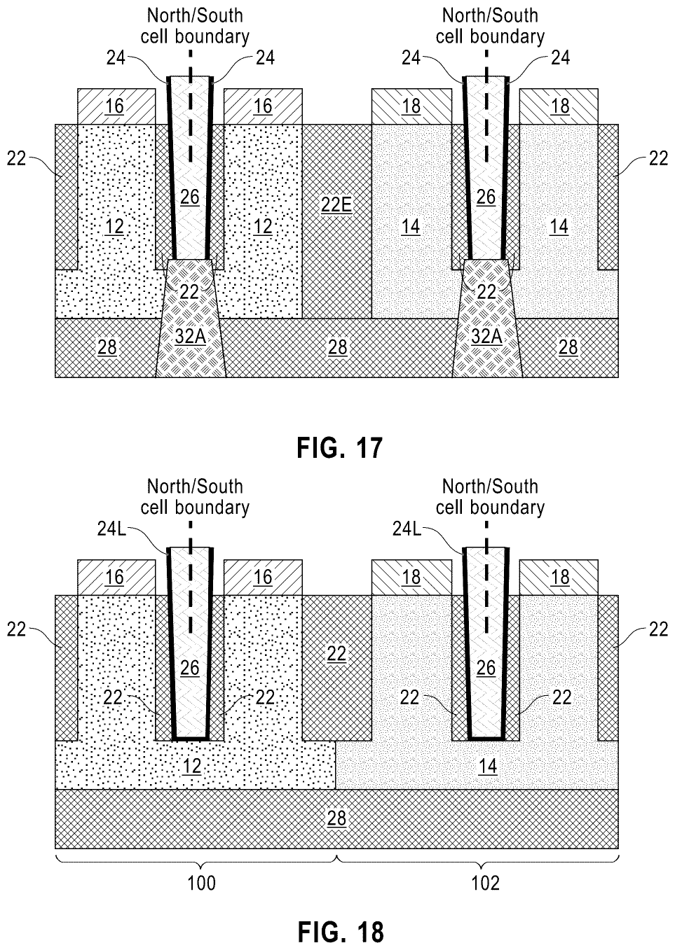

Referring now to FIG. 17, there is illustrated the exemplary semiconductor structure of FIG. 16 after forming a backside contact structure 32A in each of the backside contact openings 30. The backside contact structures 32A of this embodiment are the same as that mentioned above in forming the exemplary semiconductor structure shown in FIG. 9. As is shown, each backside contact structure 32A is in direct physical contact with at least the conductor contact pillar 26 of each conductor structure that is present in each of the pFET device region 100 and the nFET device region 102. Also, and in the present application, each backside contact structure 32A makes a sidewall connection to like well regions that straddle the backside contact structure 32A. The direct connection between the backside contact structure 32A and straddling well regions produces the backside local well tap as described above in respect to FIGS. 1, 2 and 3. In embodiments, backside contact structure 32A can be replaced with a wrap-around backside contact structure as shown in FIGS. 2 and 3.

Referring now to FIG. 18, there is illustrated the exemplary semiconductor structure of FIG. 7 after forming a backside ILD layer 28. The backside ILD layer 28 used in this embodiment is the same as that mentioned above in forming the exemplary structure shown in FIG. 8.

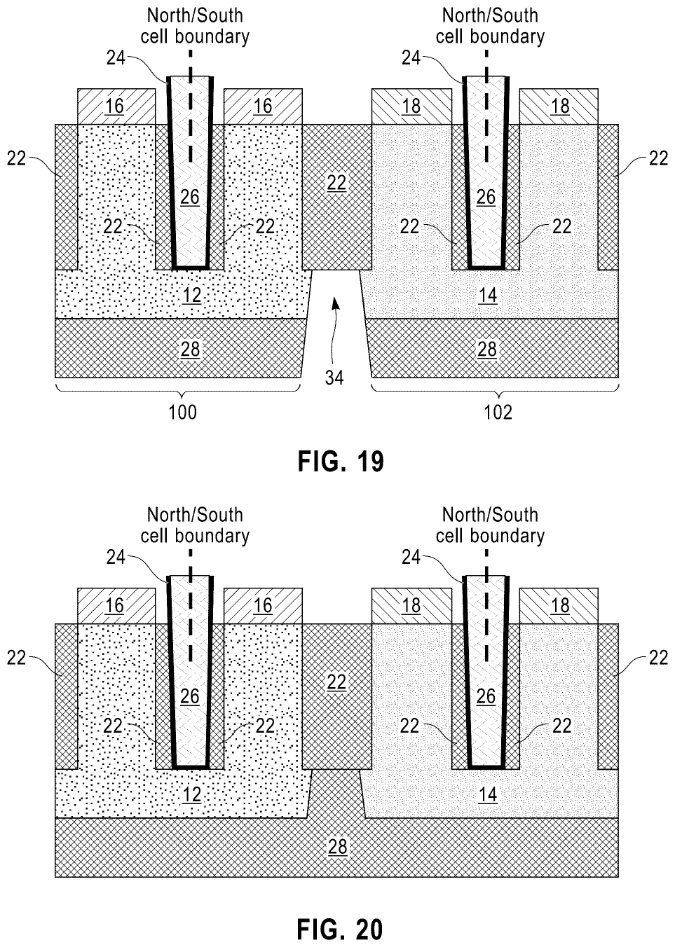

Referring now to FIG. 19, there is illustrated the exemplary semiconductor structure of FIG. 18 after forming a backside opening 34 that reveals one of the shallow trench isolation structures 22. The revealed shallow trench isolation structure 22 is the shallow trench isolation structure 22 that separates different conductivity type transistors from each other. The backside opening 34 can be formed by lithography and etching. The etching stops on the shallow trench isolation structure 22 that separates different conductivity type transistors from each other.

Referring now to FIG. 20, there is illustrated the exemplary semiconductor structure of FIG. 19 after forming additional backside ILD material in the backside opening 34 to form a backside ILD extension 28E. The additional backside ILD material is compositionally the same as the ILD material used in providing the backside ILD layer 28. The additional backside ILD material can be formed by deposition, followed by a planarization process. The backside ILD extension 28E separates the n-well region 12 from the p-well region 14 as is shown in FIG. 20.

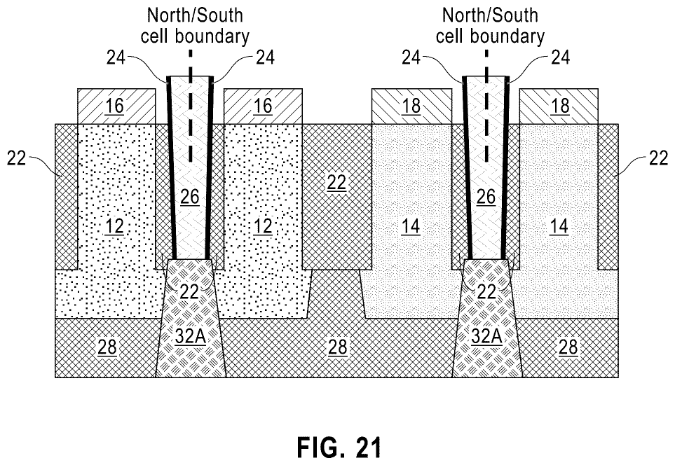

Referring now to FIG. 21, there is illustrated the exemplary semiconductor structure of FIG. 20 after forming backside contact structures 32A. The backside contact structure 32A of this embodiment are the same as that mentioned above in forming the exemplary semiconductor structure shown in FIG. 9. As is shown, each backside contact structure 32A is in direct physical contact with at least the conductor contact pillar 26 of each conductor structure that is present in each of the pFET device region 100 and the nFET device region 102. Also, and in the present application, each backside contact structure 32A makes a sidewall connection to like well regions that straddle the backside contact structure 32A. The direct connection between the backside contact structure 32A and straddling well regions produces the backside local well tap as described above in respect to FIGS. 1, 2 and 3. Note that is possible to provide a wrap-around backside contact structure (e.g., backside contact structure 32B or 32C) such as shown in FIG. 2 or 3 instead of the backside contact structure 32A).

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
two transistors of a first conductivity type located on a surface of a well region of a second conductivity type that differs from the first conductivity type;
a shallow trench isolation structure located between the two transistors of the first conductivity type;
a conductor structure located in the shallow trench isolation structure and including at least a conductor contact pillar; and
a backside contact structure electrically connected to a bottom surface of the conductor contact pillar and in direct contact with a sidewall of the well region that is located beneath each of the transistors of the first conductivity type.

2. The semiconductor device of claim 1, wherein the shallow trench isolation structure has a depth that is shallower than a depth of the well region.

3. The semiconductor device of claim 1, further comprising a backside power distribution network structure in electrical contact with the backside contact structure.

4. The semiconductor device of claim 1, wherein the conductor structure further comprises a liner present along an entirety of a sidewall of the conductor contact pillar.

5. The semiconductor device of claim 1, wherein the backside contact structure has a shape of a pyramid having a top portion electrically connected to the bottom surface of the conductor contact pillar, and a bottom portion opposite the top portion, wherein the bottom portion of the pyramid has a first critical dimension and the top portion of the pyramid has a second critical dimension less than the first critical dimension.

6. The semiconductor device of claim 1, wherein the backside contact structure is composed of a contact conductor material, and the contact conductor material is in direct physical contact with the sidewall of the well region and with the bottom surface of the conductor contact pillar.

7. The semiconductor device of claim 1, wherein the backside contact structure is composed of a silicide, and the silicide is in direct physical contact with the sidewall of the well region.

8. A semiconductor device comprising:
two transistors of a first conductivity type located on a surface of a well region of a second conductivity type that differs from the first conductivity type;
a shallow trench isolation structure located between the two transistors of the first conductivity type;
a conductor structure located in the shallow trench isolation structure and including at least a conductor contact pillar; and
a backside contact structure electrically connected to both a sidewall and a bottom surface of the conductor contact pillar of the conductor structure and in direct contact with a sidewall of the well region that is located beneath each of the transistors of the first conductivity type.

9. The semiconductor device of claim 8, wherein the shallow trench isolation structure has a depth that is shallower than a depth of the well region.

10. The semiconductor device of claim 8, further comprising a backside power distribution network structure in electrical contact with the backside contact structure.

11. The semiconductor device of claim 8, wherein the conductor structure further comprises a liner present along an upper portion of the sidewall of the conductor contact pillar.

12. The semiconductor device of claim 8, wherein the backside contact structure has a shape of a pyramid having a top portion electrically connected to both the sidewall and the bottom surface of the conductor contact pillar, and a bottom portion opposite the top portion, wherein the bottom portion of the pyramid has a first critical dimension and the top portion of the pyramid has a second critical dimension less than the first critical dimension.

13. The semiconductor device of claim 8, wherein the backside contact structure is composed of a contact conductor material, and the contact conductor material is in direct physical contact with the sidewall of the well region and with both the sidewall and the bottom surface of the conductor contact pillar.

14. The semiconductor device of claim 8, wherein the backside contact structure is composed of a silicide, and the silicide is in direct physical contact with the sidewall of the well region.

15. A semiconductor device comprising:
two transistors of a first conductivity type located on a surface of a well region of a second conductivity type that differs from the first conductivity type;
a shallow trench isolation structure located between the two transistors of the first conductivity type;
a conductor structure located in the shallow trench isolation structure and including at least a conductor contact pillar; and
a backside contact structure electrically connected to both a sidewall and a bottom surface of the conductor contact pillar of the conductor structure and in direct contact with both a sidewall and a bottom surface of the well region that is located beneath each of the transistors of the first conductivity type.

16. The semiconductor device of claim 15, further comprising a backside power distribution network structure in electrical contact with the backside contact structure.

17. The semiconductor device of claim 15, wherein the conductor structure further comprises a liner present along an upper portion of the sidewall of the conductor contact pillar.

18. The semiconductor device of claim 15, wherein the backside contact structure has a shape of a pyramid having a top portion electrically connected to the bottom surface of the conductor contact pillar, and a bottom portion opposite the top portion, wherein the bottom portion of the pyramid has a first critical dimension and the top portion of the pyramid has a second critical dimension less than the first critical dimension.

19. The semiconductor device of claim 15, wherein the backside contact structure is composed of a contact conductor material, and the contact conductor material is in direct physical contact with the bottom surface and the sidewall of the well region and with the sidewall and bottom surface of the conductor contact pillar.

20. The semiconductor device of claim 15, wherein the backside contact structure is composed of a silicide, and the silicide is in direct physical contact with the bottom surface and the sidewall of the well region.

21. A semiconductor device comprising:
a pFET device region comprising two p-type field effect transistors (pFETs) located on a surface of an n-well region, a first shallow trench isolation structure located between the two pFETs, a first conductor structure located in the first shallow trench isolation structure and including at least a first conductor contact pillar, and a first backside contact structure electrically connected to at least a bottom surface of the first conductor contact pillar of the first conductor structure and in direct contact with a sidewall of the n-well region; and
an nFET device region located adjacent to the pFET device region and comprising two nFETs located on a surface of a p-well region, a second shallow trench isolation structure located between the nFETs, a second conductor structure located in the second shallow trench isolation structure and including at least a second conductor contact pillar, and a second backside contact structure electrically connected to at least a bottom surface of the second conductor contact pillar of the second conductor structure and in direct contact with a sidewall of the p-well region.

22. The semiconductor device of claim 21, wherein the n-well region and the p-well region are in contact with each other under a third shallow trench isolation structure that separates the pFET device region from the nFET device region.

23. The semiconductor device of claim 21, wherein the n-well region and the p-well region are physically separated from each other.

24. The semiconductor device of claim 21, wherein each of the first backside contact structure and the second backside contact structure is a wrap-around backside contact structure.

25. The semiconductor device of claim 21, further comprising a backside power distribution network structure in electrical contact with the first backside contact structure and with the second backside contact structure.
